(19) United States
(12) Patent Application Publication
(10) Pub. No.: US 2025/0301584 A1
(43) Pub. Date: Sep. 25, 2025

(54) PANEL MOUNTING IN A CUTOUT

(71) Applicant: WAGO Verwaltungsgesellschaft mbH, Minden (DE)

(72) Inventors: Hans GIERLICH, Kirchheim unter Teck (DE); Lars BINNER, Melle (DE)

(73) Assignee: WAGO Verwaltungsgesellschaft mbH, Minden (DE)

(21) Appl. No.: 19/086,052

(22) Filed: Mar. 20, 2025

(30) Foreign Application Priority Data
Mar. 20, 2024 (DE) 20 2024 101 415.4

(51) Int. Cl. H05K 5/02; H05K 5/00

(52) U.S. Cl. CPC H05K 5/0217; H05K 5/0018

(57) ABSTRACT

A panel including a housing arranged on a back side of the panel, and first and second fastening claws. The first and second fastening claws are arranged on different sides of the housing or opposite each other on the housing. Each of the first and second fastening claws comprise a first section having an elongated opening or a slot, into which a fastening element extending from the housing engages. Each of the first and second fastening claws comprises a second section which, in a first position, rests against the housing and, in a second position, rests against a back side of a structure that surrounds a cutout in which the panel is mounted. A first surface region in the housing is formed around each of the fastening elements with a second surface region adjoining the first surface region towards a housing center line or a housing center.

This nonprovisional application claims priority under 35 U.S.C. § 119 (a) to German Patent Application No. 20 2024 101 415.4, which was filed in Germany on Mar. 20, 2024, and which is herein incorporated by reference.

### BACKGROUND OF THE INVENTION

### Field of the Invention

The present invention relates to a panel which is to be mounted in a cutout. In particular, the present invention relates to a panel having fastening claws arranged on the back side of the panel which secure the panel in the cutout by resting against the back side of the structure surrounding the cutout.

### Description of the Background Art

For control purposes, a system may comprise a panel with a touch-sensitive screen. The panel may be inserted into a cutout and fastened there such that the panel only protrudes slightly above the surface surrounding the panel and is thus perceived as an integral part of the system.

### SUMMARY OF THE INVENTION

A panel according to an example of the invention comprises a housing arranged on a back side of the panel, a first fastening claw, and a second fastening claw, wherein the fastening claws are arranged on different sides of the housing or opposite each another on the housing. Each of the fastening claws can comprise a first section having an elongated opening, in particular a slot, into which a fastening element extending from the housing engages.

Each of the fastening claws can further comprise a second section which, in a first position, rests against the housing and, in a second position, rests against a back side of a structure which surrounds a cutout in which the panel is arranged. A first surface region in the housing can be formed around each of the fastening elements with a second surface region adjoining the first surface region towards a housing center line or a housing center. The second surface region forms a recess into which the first section at least partially dives when the second section, initially being in the first position, is pivoted away from the structure.

The panel may comprise a touch-sensitive screen arranged on a front side of the panel.

In this regard, the term ‘panel’, may refer to a structure of which only a part is visible when fastened, forming a substantially rectangular plate-shaped structure which conceals a structure located behind it. Furthermore, the term ‘touch-sensitive screen’, may refer to a screen which is provided with a touch-sensitive surface, wherein inputs can be made via the touch-sensitive surface during operation, with inputs being received by a computer which displays an input mask on the screen.

Furthermore, the term ‘housing’ may refer to a rigid structure which covers the back of the touch-sensitive screen and/or, together with the touch-sensitive screen, encloses a cavity in which, for example, the computer may be arranged. In addition, the term ‘fastening claw’, may refer to a component which is configured to prevent movement of the panel relative to the cutout parallel to the surface of the screen by frictional engagement with the structure that surrounds the cutout.

Each of the first surface areas may comprise a hole and the fastening element may be a screw engaged in the hole. The hole may be provided with an internal thread (tapped hole) or the screw may cut an internal thread into the hole when screwed into the hole. If the screw is not tightened, the screw loosely connects the mounting claw to the housing. When the screw is tightened, the mounting claw is fastened to the housing.

The first surface area may be plane, and the first section of the fastening claw may have a plane surface segment around the elongated opening facing the housing. The plane surface segment may abut the first surface region if the fastening claw is fastened to the housing.

The plane surface segment may abut the second surface region if the fastening claw is loosely connected to the housing and the second section, initially being in the first position, is pivoted away from the structure as far as possible.

The first section and the second section may be angled to one another. The first section and the second section may enclose an angle of 70° to 110° (e.g., 90°) with each other.

The second section may be U-shaped and each of the fastening claws may comprise a third section extending between the legs of the U-shaped second section from its base and forming a V-shaped projection configured to snap rearwardly behind an edge of the structure when the panel is inserted into the cutout to temporarily fix the panel in a mounting position.

Each of the fastening claws may be made in one piece. The fastening claws may be spring claws. The fastening claws may be made from metal. The fastening claws may be punch-bent parts.

The structure may be formed by a wall or a door leaf of a door. By pivoting the second section away from the structure before pulling out the fastening claw (as far as possible), the wall or door leaf and any seal attached to the wall or door leaf can be protected from being excessively stressed or even damaged.

Furthermore, it is understood that the features described in connection with the panel may also be features of a method in which the panel is fastened in the cutout, and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a is a schematic depiction of a front side of a panel mounted in a cutout;

FIG. 1b shows a cross-section through the panel shown in FIG. 1a;

FIG. 2 is a perspective view of a panel and a cutout in which the panel can be mounted;

FIG. 3 shows an enlarged section of the illustration shown in FIG. 2;

FIG. 4 shows a sectional perspective of a panel which is inserted into a cutout and is held there in a mounting position by the fastening claws before the final mounting;

FIG. 5 is a perspective view of a fastening claw in a first position in which the fastening claw rests against the housing;

FIG. 6 is a perspective view of a first surface area and a second surface area of the housing which are (at least partially) covered by the fastening claw shown in FIG. 5 when the fastening claw is in the first position;

FIG. 6a shows a first fastening element which may be attached to the housing in the first surface area;

FIG. 6b shows a second fastening element which may be attached to the housing in the first surface area;

FIG. 7 is a side view of the fastening claw shown in FIG. 6, in which the second section, initially being in the first position, is pivoted away from the structure;

FIG. 8 is a perspective view of the fastening claw shown in FIG. 6, in which the second section, initially being in the first position, is pivoted away from the structure;

FIG. 9 is a side view of the fastening claw in the second position;

FIG. 10 is a perspective view of the front side of the panel mounted in the cutout; and

FIG. 11 is a perspective view of the back side of the panel mounted in the cutout.

### DETAILED DESCRIPTION

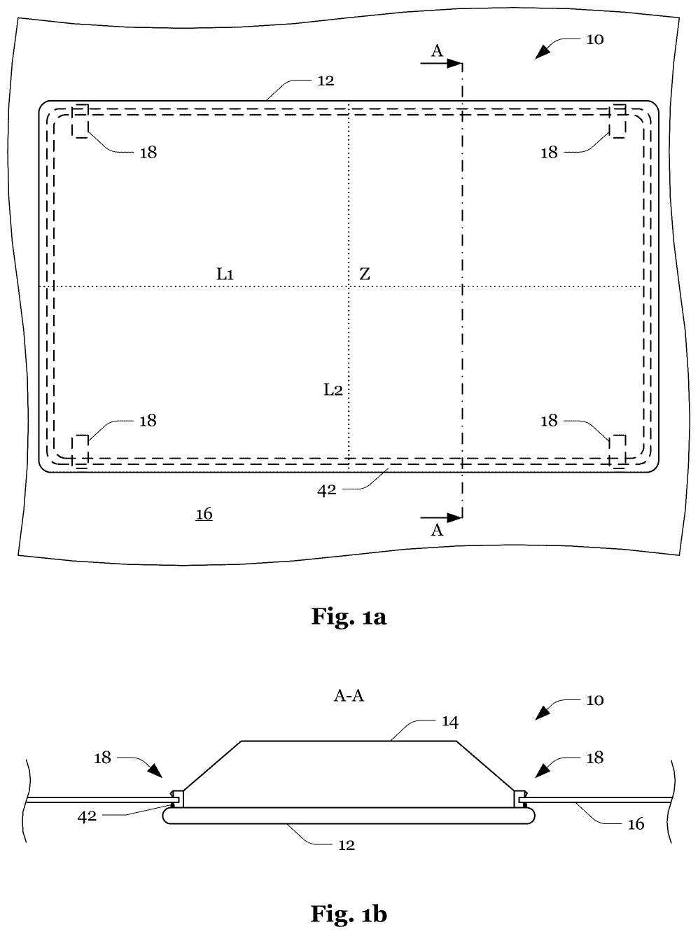

FIG. 1a and FIG. 1b show a front view and a cross-section of a panel 10 mounted in a cutout. The panel 10 has a touch-sensitive screen 12 arranged on the front side of the panel 10 and a housing 14 arranged on the back side of the panel 10. The touch-sensitive screen 12, or a transparent plate forming the touch-sensitive surface of the screen 12, protrudes beyond the cutout on all sides, thus securing the position of the panel 10 against displacement towards the back side.

Furthermore, fastening claws 18 are arranged on the top and bottom of the housing 14 and rest against the back of the structure 16 surrounding the cutout. This secures the position of the panel 10 against displacement towards the front side. In addition, the fastening claws 18 prevent a movement of the panel 10 relative to the cutout parallel to the surface of the screen 16 by providing a frictional engagement between the seal 42, which is attached (e.g., glued) to the back side edge of the touch-sensitive screen 12, and the structure 16, such that the position of the panel 10 is completely fixed relative to the cutout.

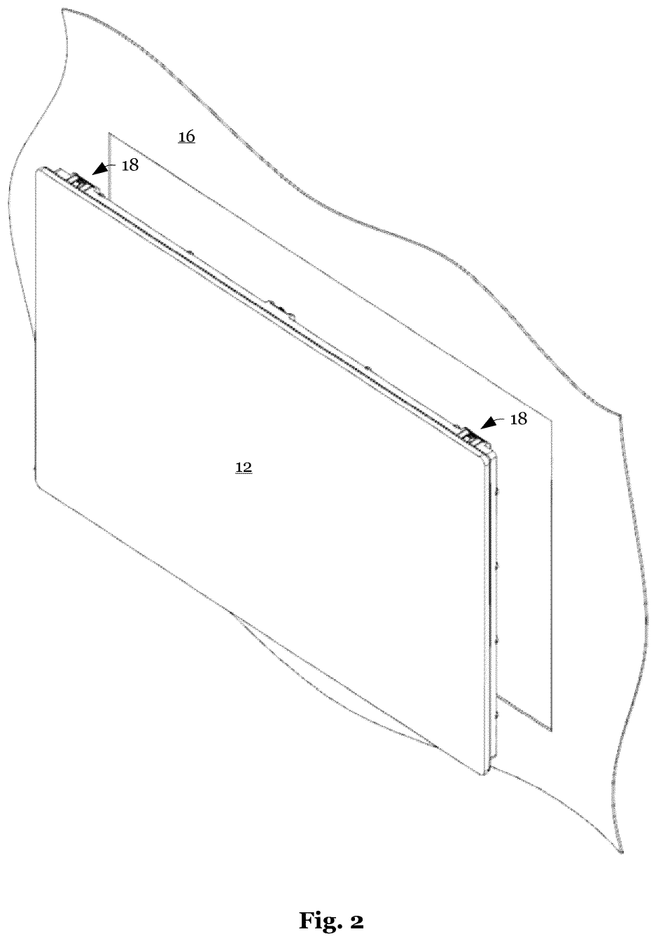

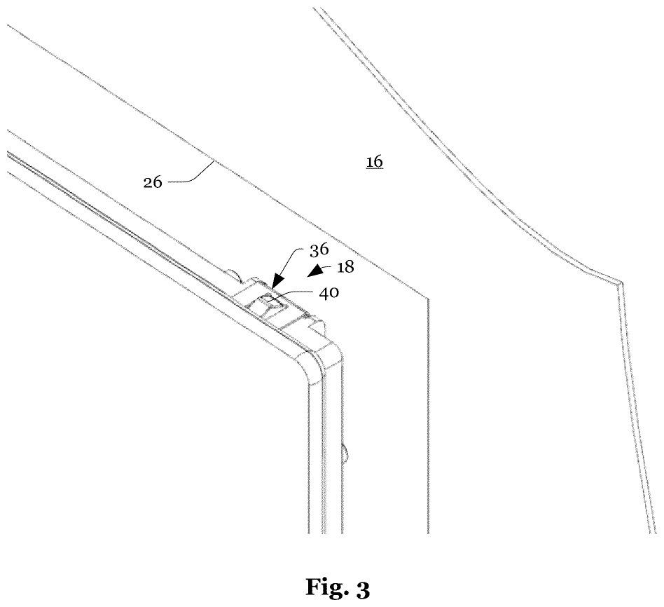

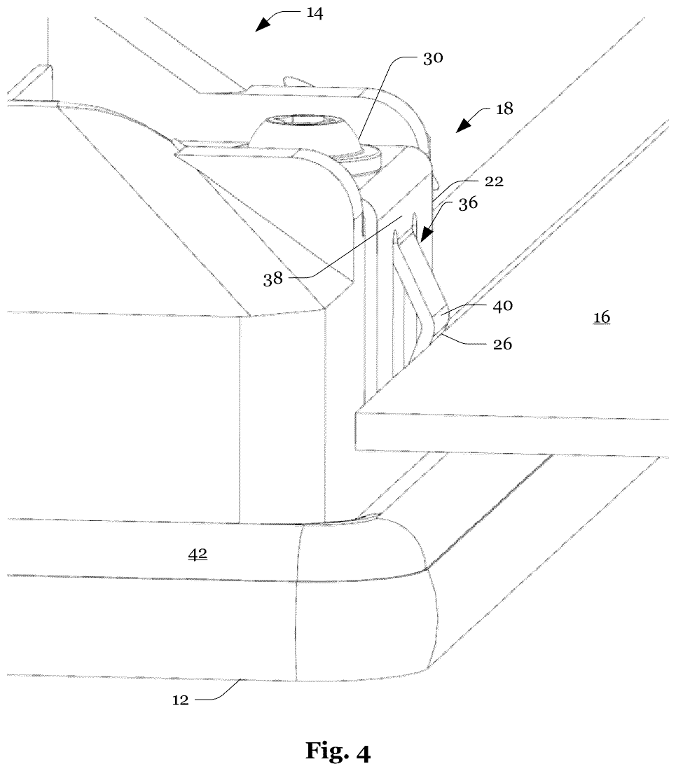

FIG. 2 shows a perspective view of a panel 10 according to an example and a cutout (adapted to the size of the panel 10) in which the panel 10 is to be mounted. To simplify mounting, the fastening claws, as shown in FIG. 3 and FIG. 4, have a portion 36 which forms a V-shaped projection 40 which snaps rearwardly behind the edge of the structure 16 to temporarily fix the panel 10 in the mounting position when the panel 10 is inserted into the cutout.

The V-shaped projection 40 has a free end which is spaced from the housing 14 such that the projection 40 can be displaced in the direction of the housing 14 against a restoring force. The shape of the projection 40 not only allows the panel 10 to be pushed into the cutout but also allows the panel 10 to be removed from the cutout as long as the panel 10 is still in the mounting position (i.e., as long as the fastening claws 18 are still retracted and rest against the housing 14).

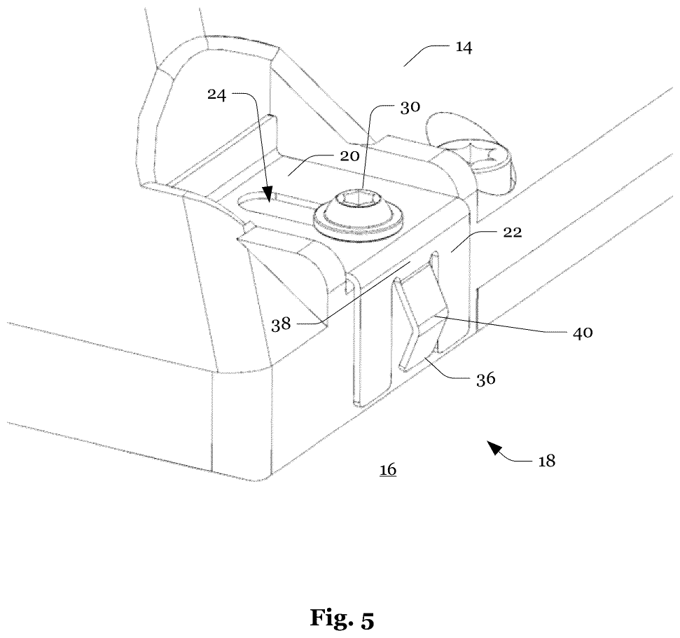

FIG. 5 shows a perspective view of the fastening claws 18 shown in FIG. 2 to FIG. 3. The fastening claw 18 shown comprises a first section 20 and a second section 22, which enclose an angle of 90° with each other. The first section 20 comprises an elongated opening 24 (in the form of a slot) into which a fastening element 30 extending from the housing 14 engages. The second section 22 is U-shaped and abuts the housing 14, while the V-shaped projection 40 forms a third section 36 extending from the base 38 of the U-shaped second section 22.

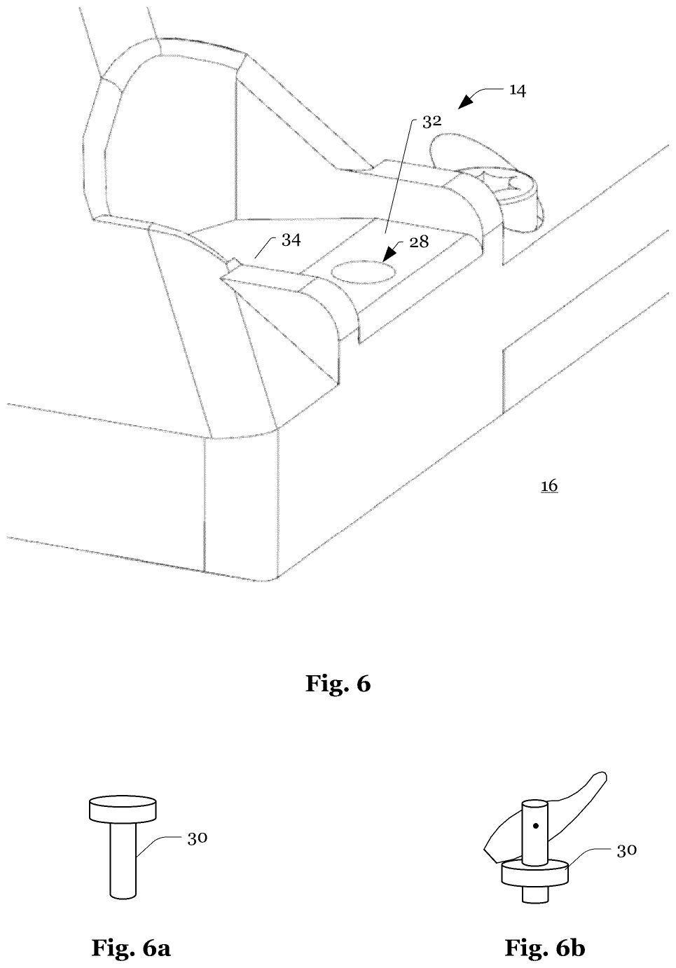

As shown in FIG. 6, the first section 20 covers a first surface area 32 and a second surface area 34 of the housing 14, wherein the second surface area 34 adjoins the first surface area 32 in the direction of the housing center line L1 shown in FIG. 1. As indicated in FIG. 6, the first surface region 32 comprises a hole 28 into which a fastening element 30, for example a fastening element 30 in the form of a screw, as (schematically) shown in FIG. 4, FIG. 5, or FIG. 6a, or a fastening element 30 in the form of a quick release, as shown in FIG. 6b, may be screwed.

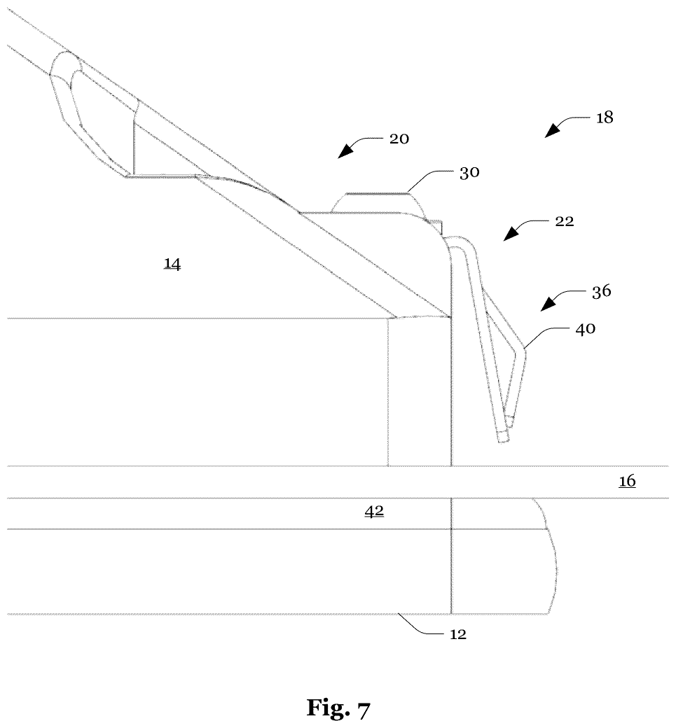

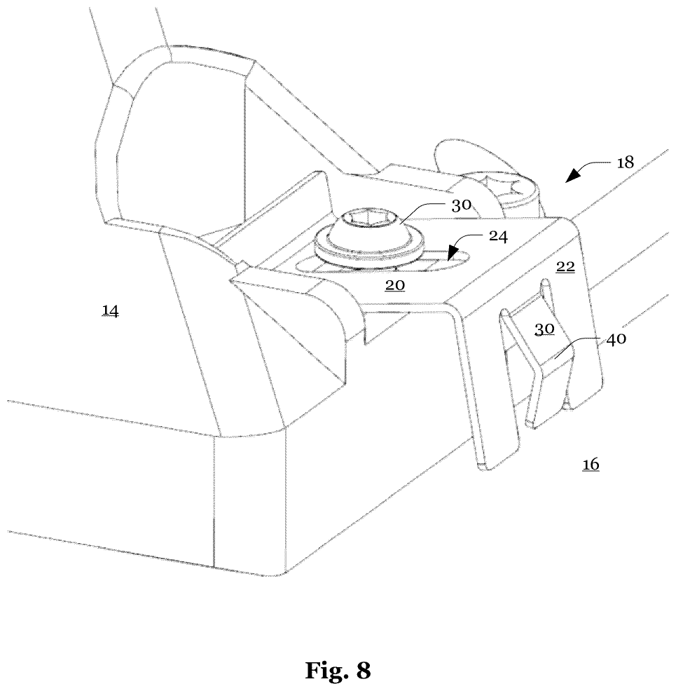

As shown in FIG. 7 and FIG. 8, after the panel 10 has been fully inserted into the cutout and the screen 12 or the seal 42 applied to the back side of the screen 12 is in contact with the structure 16, the fastening element 30 can be loosened and the second section 22, initially being in the first position as shown in FIG. 5, can be pivoted away from the structure 16. Because the second surface region 34 forms a recess, as shown in FIG. 6, pivoting away is facilitated since the first section 20 can at least partially dive into the recess if the second section 22, initially being in the first position as shown in FIG. 5, is pivoted away from the structure 16.

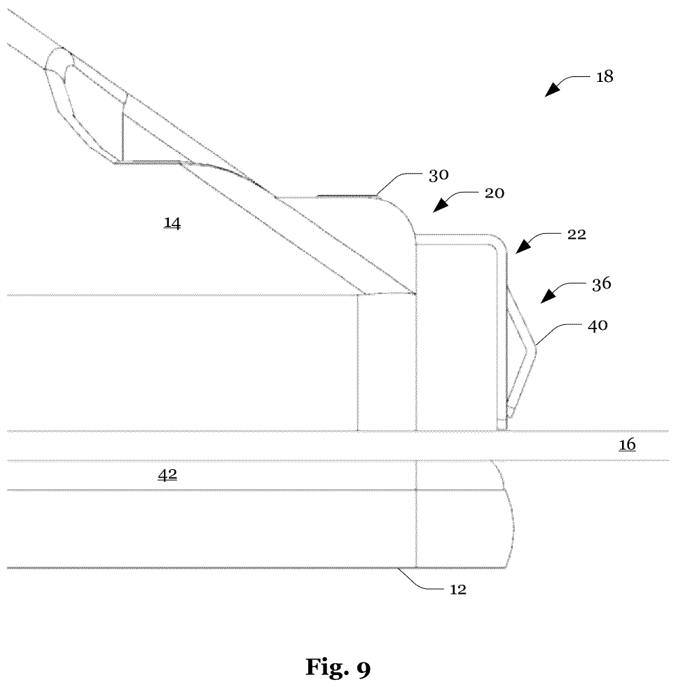

Facilitating the pivoting away of the second section 22 makes it easier to slide the fastening claw 18 outwardly relative to the housing 14 (utilizing the play provided by the elongated opening 24) without the free end of the second portion 22 coming into contact with the seal 42 or the structure 16 and stressing or damaging the surface of the structure 16 or resulting in excessive compression of the seal 42. When moving, the first section 20 can slide along the first surface area 20 until the fastening claw 18 has been moved outwardly as far as possible. The fastening element 30 can then be refastened, thereby pushing the free end of the second portion 22 against the structure 16, as shown in FIG. 9, and thus compressing the seal 42 by the desired amount and fixing the position of the panel 10 relative to the cutout.

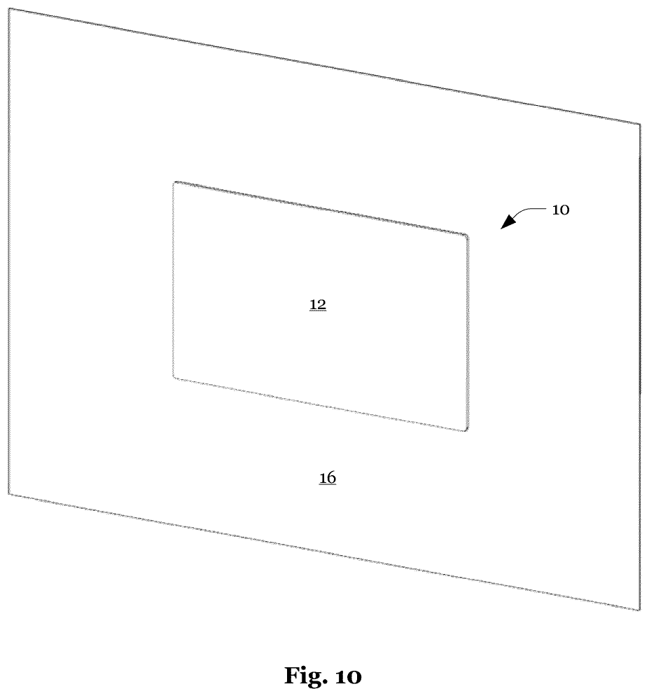

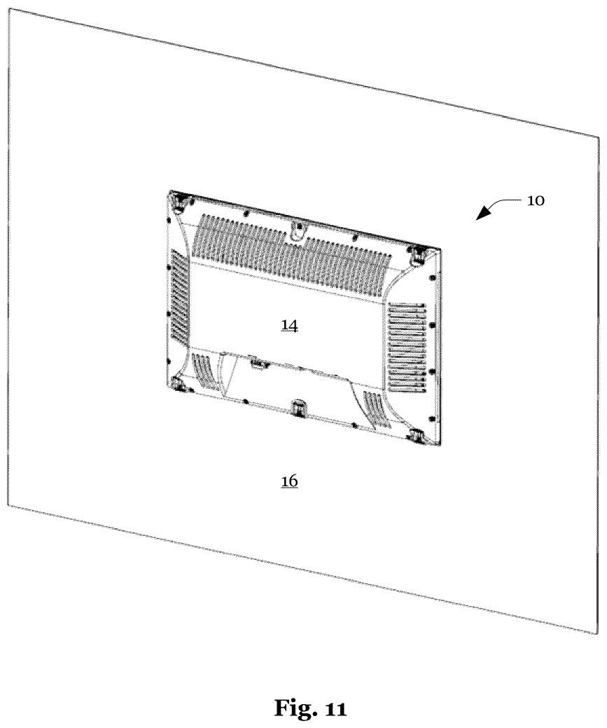

FIG. 10 shows a perspective view of the front side of the panel 10 fastened in the cutout. The panel 10 is inserted so far into the cutout that only the touch-sensitive screen 12 is visible. FIG. 11 shows a perspective view of the back side of the panel 10 mounted in the cutout.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A panel comprising:
a housing arranged on a back side of the panel;
a first fastening claw; and
a second fastening claw,
wherein the first and second fastening claws are arranged on different sides of the housing or opposite each other on the housing,
wherein each of the first and second fastening claws comprise a first section having an elongated opening or a slot, into which a fastening element extending from the housing engages,
wherein each of the first and second fastening claws comprises a second section which, in a first position, rests against the housing and, in a second position, rests against a back side of a structure that surrounds a cutout in which the panel is mounted,
wherein a first surface region in the housing is formed around each of the fastening elements with a second surface region adjoining the first surface region towards a housing center line or a housing center, and
wherein the second surface region forms a recess into which the first section at least partially dives when the second section, initially being in the first position, is pivoted away from the structure.

2. The panel of claim 1, further comprising a touch-sensitive screen arranged on a front side of the panel.

3. The panel of claim 1, wherein each of the first surface regions comprise a hole, wherein the fastening element is a screw is adapted to engage in the hole, wherein the screw loosely connects the fastening claw to the housing if the screw is not tightened, and wherein the fastening claw is fastened to the housing if the screw is tightened.

4. The panel of claim 3, wherein the first surface region is a plane, wherein the first section of the fastening claw has a plane surface segment around the elongated opening facing the housing, and wherein the plane surface segment abuts the first surface region if the fastening claw is fastened to the housing.

5. The panel of claim 4, wherein the second surface region is plane, and wherein the plane surface segment abuts the second surface region if the fastening claw is loosely connected to the housing and the second section, initially being in the first position, is pivoted away from the structure as far as possible.

6. The panel of claim 1, wherein the first section and the second section are angled to one another and enclose an angle of 90° with one another.

7. The panel of claim 6, wherein the second section is U-shaped, and wherein each of the fastening claws comprises a third section extending between the legs of the U-shaped second section from its base and forming a V-shaped projection configured to snap rearwardly behind an edge of the structure when the panel is inserted into the cutout to temporarily fix the panel in a mounting position.

8. The panel of claim 1, wherein each of the first and second fastening claws is made in one piece and/or from a metal.

9. The panel of claim 8, wherein each of the first and second fastening claws is a punch-bent part.

10. The panel of claim 1, wherein the first and second fastening claws are spring claws.

11. A system comprising a panel according to claim 1, and a wall or a door, wherein a structure is formed by the wall or a door leaf of the door.
